(19) United States
(12) Patent Application Publication
(10) Pub. No.: US 2023/0130419 A1
(43) Pub. Date: Apr. 27, 2023

(54) METHOD FOR CLEANING SEMICONDUCTOR DEVICES

(71) Applicant: ASMPT NEXX, INC., Billerica, MA (US)

(72) Inventors: William SOLARI, Billerica, MA (US); Ivo STASSEN, Billerica, MA (US); Dolores CRUZ, Billerica, MA (US); David GUARNACCIA, Billerica, MA (US); Khaled ALI HASSAN, Billerica, MA (US)

(21) Appl. No.: 17/507,129

(22) Filed: Oct. 21, 2021

(51) Int. Cl. H01L 21/67; H01L 21/02; C25D 17/00

(52) U.S. Cl. CPC H01L 21/67057; H01L 21/6723; H01L 21/02074; C25D 17/001; C25D 17/02

(57) ABSTRACT

A method of cleaning a conducting film containing tin oxide from an insulating surface of an item for use in electroplating applications, comprises the steps of immersing the item in a cleaning fluid and irradiating the immersed item with light of wavelength in the range 100 nm-450 nm.

### BACKGROUND OF THE INVENTION

Electroplating is used as a manufacturing method for applying thin films and to build up interconnect features on semiconductor wafers and panel substrates. Substrate holders may be used to transport wafer and panel substrates between process steps including pre-wet, activation, electroplating, rinsing and drying. During the electroplating process step, features in substrate holders provide electrical contact to substrates. Other features provide a fluid seal near the interface area between the electrical contacts and the substrate. The seal prevents the electroplating bath from making direct electrical contact with the interface. The features providing electrical contact are fabricated from conducting metal. These features are insulated from the plating bath by insulating material, typically an elastomeric rubber formed in a molding operation.

After electroplating, substrates are typically rinsed with deionized water to remove residual plating bath, and then dried. Substrate holders may also be rinsed and dried. Most electroplating bath residue is removed during the rinse operation, but some bath chemistry can leave residue on the substrate holder.

Baths for tin, tin-silver and other tin alloys are well known to leave trace amounts of tin-oxide residue on the surface of substrate holders. After repeated electroplating-rinse-dry cycles this residue can build up sufficiently to create a thin conducting film on the surface of the insulating substrate holder. In more detail, the film may comprise hydrated and oxidized mixtures of tin and other bath constituents (for example organic molecules, and if silver is present in the bath, oxides and hydrated silver species are typically incorporated into the mixture). It has been found that oxides and hydrates species of tin will typically constitute at least 50% of the film formed for standard plating baths, providing a strong peak in energy dispersive spectroscopy (EDS) analyses, though naturally this may vary significantly depending on the exact bath chemistry used for the particular application. Such tin oxides tend to form islands of amorphous “blobs” on the surface, and if these islands grow to the extent that they touch each other then conductive paths may be formed. If the conducting film makes contact with either the substrate or the electrical contacts of the substrate holder, plating may occur on the substrate holder. This condition is known in the industry as “plate-out”. Plate-out is undesirable because it can direct current away from the substrate, leading to non-uniform plating. Metal particles from plate-out may also become detached from the substrate holder providing a source of contamination for the electrical wiring or interconnects of the substrate. The industry places strict limits on the amount and size of such particle contamination.

Tin oxide adheres strongly to insulating surfaces including plastics and elastomeric materials. There are a limited number of chemical methods to remove a thin film of tin oxide. Methods using pure acids and bases are not effective at removing the film. A combination of zinc powder and hydrochloric acid can be used to etch tin oxide, but is not a method applicable to cleaning of substrate holders. As a result, prior art methods to prevent tin-oxide plate-out typically employ manual cleaning of substrate holders, typically done using abrasive pads and water rinse. However, manual cleaning operations can require significant tool downtime for maintenance. Establishing a reliable cleaning method is difficult, as aggressive cleaning can cause damage to the substrate holder and insufficient cleaning can lead to plate-out.

It is an object of the present invention to provide an automated module which can be used to replace manual cleaning of tin-oxide films on substrate holders. The present invention achieves this object by providing a cleaning method using a combination of chemistry and UV light which will not damage the substrate holder during cleaning, as well as apparatus to perform such a cleaning method.

In preferred embodiments of the invention, conducting films containing tin oxide are cleaned from the insulating surfaces of substrate holders used in semiconductor electroplating, preventing subsequent metal plating on the substrate holders by treatment with a combination of chemistry and UV light followed by rinsing and drying steps.

Proposed method steps include, but are not limited to: inserting a substrate holder in a treatment tank, flexing the holder to allow chemical access to insulating surfaces, supplying a concentrated chemistry, applying UV light at wavelengths between 100-450 nm, agitating the chemical solution, recycling the chemical solution to a holding tank, providing water for rinsing and providing air for drying.

The cleaning apparatus advantageously comprises a treatment tank with features to accept and flex a substrate holder, to provide chemical and UV light access to the insulating surfaces of the substrate holder, to provide agitation during processing, and to rinse and dry the substrate holder.

Because the residue mixture is not of well-defined composition (in particular it is not rutile crystalline tin oxide with a known band-gap), the effect of light and chemistry on the mixture is unknown. Experimental tests have shown that certain alkaline and acid chemistry combined with particular light wavelengths are effective at cleaning the residue.

In accordance with a first aspect of the present invention there is provided a method of cleaning a conducting film containing tin oxide from an insulating surface of an item for use in electroplating applications, comprising the steps of:
i) immersing the item in a cleaning fluid; and
ii) irradiating the immersed item with light of wavelength in the range 100 nm-450 nm.

In accordance with a second aspect of the present invention there is provided a cleaning apparatus for cleaning a conducting film containing tin oxide from an insulating surface of an item for use in electroplating applications, comprising:
a tank holding cleaning fluid in use,
a support for supporting the item within the tank so that it is immersed in the cleaning fluid,
a light source configured to irradiate the item while immersed in the cleaning fluid, the light source operative to emit light in the wavelength in the range 100 nm-450 nm.

In accordance with a third aspect of the present invention there is provided an electroplating machine comprising the cleaning apparatus of the second aspect.

In this specification, the term “conducting film” means a film that is both sufficiently thick and electrically conducting to the extent that presence of the film on the item can cause plate-out to occur.

In this specification, the term “film containing tin oxide” means a film that comprises at least 1% tin oxide by volume, optionally at least 10% tin oxide by volume, optionally at least 20% tin oxide by volume, optionally at least 30% tin oxide by volume, optionally at least 40% tin oxide by volume, optionally at least 50% tin oxide by volume as measured using energy dispersive spectroscopy (EDS), X-ray fluorescence (XRF) or a similar analytical technique.

### BRIEF DESCRIPTION OF THE DRAWINGS

FIG. 1 schematically shows an isometric view of a prior art substrate holder for circular substrates;

FIG. 2 schematically shows an isometric view of a prior art substrate holder for rectangular substrates;

FIG. 3 schematically shows an isometric view of a prior art panel substrate holder also showing a panel workpiece;

FIG. 4A schematically shows a section of a contact seal strip of FIG. 3 in a closed configuration;

FIG. 4B schematically shows a section of the contact seal strip of FIG. 4A in an open configuration;

FIG. 5 schematically shows an elevation view of the process tanks and associated fluid handling hardware for an automated cleaning module;

FIG. 6 schematically shows an elevation view of the process tanks components and components of an automated cleaning module;

FIG. 7 schematically shows a plan view of components of an automated cleaning module;

FIG. 8 schematically shows a plan view of an illumination source;

FIG. 9 schematically shows an elevation view of an automated cleaning module;

FIG. 10 schematically shows a plan view of an automated cleaning module with substrate holders inserted; and

FIG. 11 graphically depicts a light spectrum from an illumination source suitable for use with the present invention.

### DETAILED DESCRIPTION

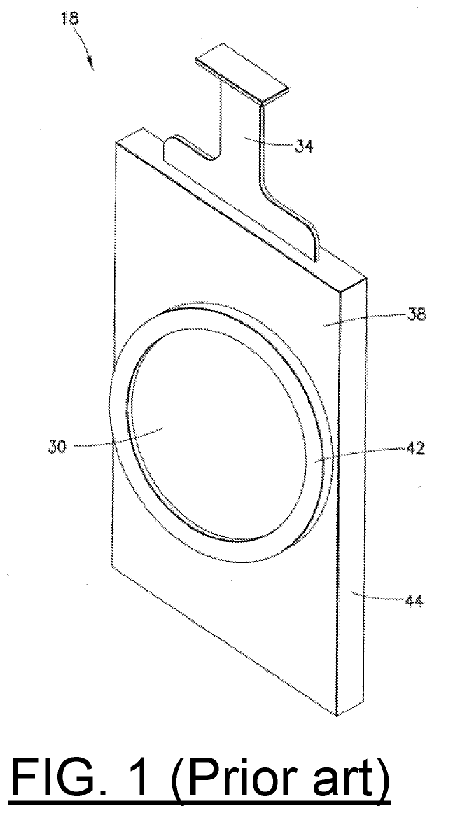

FIG. 1 shows an exemplary workpiece holder 44 for electroplating of circular semiconductor substrates. The workpiece holder is capable of holding two substrates 30 back-to-back. The workpiece holder 44 also includes a body 38, a handle 34 for transporting the holder and a substrate holder ring 42 for capturing substrate 30. Substrate holder ring 42 provides an electrical connection to the substrate as well as a fluid seal. Fluid sealing by substrate holder ring 42 prevents plating bath from entering the interface area where metal electrical contacts are in physical contact with the substrate. The substrate holder ring 42 comprises a conducting inner core and an insulating outer coating. The coating may for example be of Viton® rubber or other insulating material which is chemically compatible with plating bath chemistry. An example workpiece holder 44 and contact substrate holder ring 42 is described in U.S. Pat. No. 6,251,250 assigned to ASM NEXX Inc., and incorporated herein by reference.

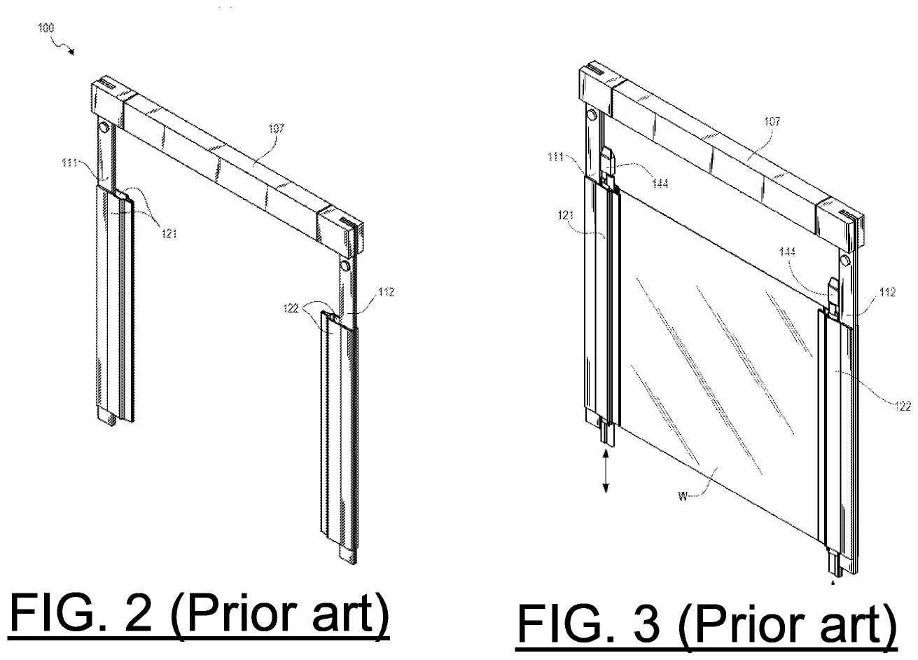

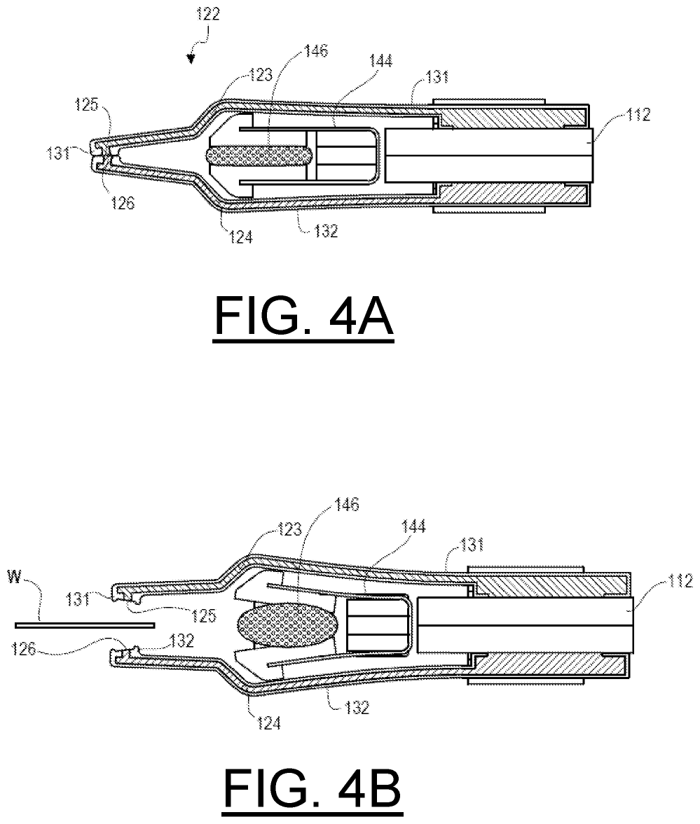

FIG. 2 shows an exemplary workpiece holder 100 for electroplating of rectangular substrates (see FIG. 3). Workpiece holder 100 comprises a header member 107 from which flexure legs 111 and 112 depend, and substrate holders in the form of contact seal strips 121 and 122 which act to grip a workpiece or substrate in use, as described in more detail below. The contact seal strips 121 and 122 comprise a central core of flexible conducting metal and an outer elastomeric insulating layer, shown in more detail in FIGS. 4A and 4B. Similar to the circular substrate holder ring 42 of FIG. 1, the contact seal strips 121 and 122 also provide electrical connection to the substrate as well as a fluid seal.

FIG. 3 shows the workpiece holder 100 with the contact seal strips 121 and 122 holding a substrate W, and also shows an elongated pneumatic actuator 144. The pneumatic actuator 144 is used in process modules where workpieces are to be loaded or unloaded or whenever else necessary to effect opening and closing of contact seal strips 121 and 122. An example workpiece holder 100, contact seal strips 121 and 122 and elongated pneumatic actuator 144 are described in U.S. patent Ser. No. 10/283,396, and incorporated herein by reference.

FIG. 4A shows the contact seal strip 122 in a closed configuration with pneumatic actuator 144 in an unpressurized state. The contact seal strip 122 consists of an inner conducting flexure structure 123, an insulating covering 131 and electrical contacts 125 and 126. The pneumatic actuator 144 comprises an inflatable bladder 146 and flexible arms 145. In the closed position, the portions of the insulating covering 131 near electrical contacts 125 and 126, which provide workpiece gripping surfaces operative to grip a workpiece therebetween in use, are inaccessible to cleaning. FIG. 4B shows pneumatic actuator 144 in an open configuration with the inflatable bladder 146 in a pressurized state. When the bladder 146 inflates, it causes the flexible arms 145 to flex outwardly and so apply pressure against the inner walls of the contact seal strip 122, opening the flexure structure 123 so that the portions of the insulating covering 131 near contacts 125 and 126 become accessible for cleaning. The contact seal strip 121 is constructed similarly to the contact seal strip 122.

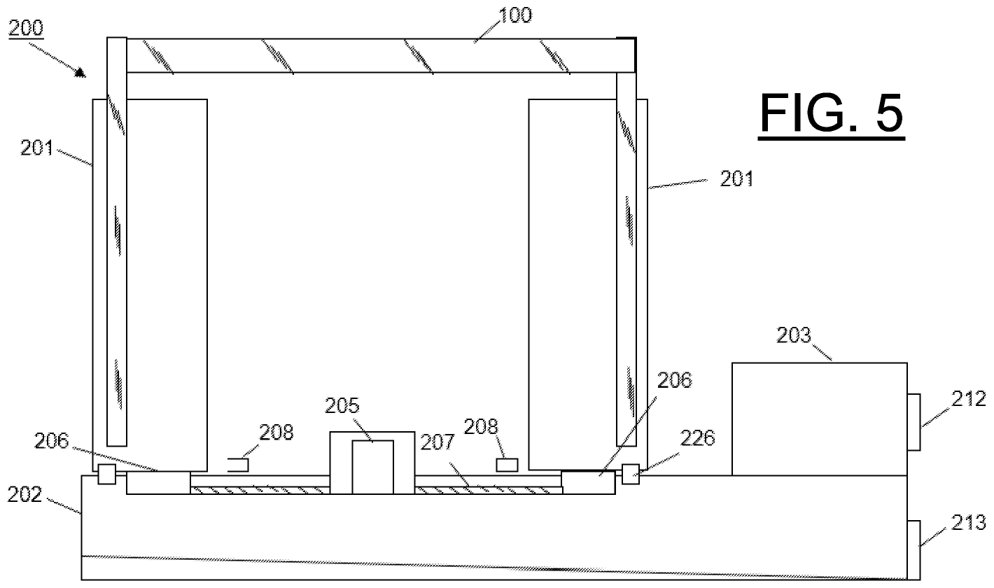

FIG. 5 shows tanks and fluid handling components of an automated cleaning module 200 according to an embodiment of the present invention holding a workpiece holder 100. The cleaning module 200 includes two process tanks 201, which may each drain into a common drain tank 202 upon opening of respective outlet plugs 206, and a vapor-separating dryer tank 203 mounted on the drain tank 202. Two inlets 208, each associated with a respective process tank 201, allow filling of the respective process tanks 201 with either chemical cleaning solution or rinse water as required. A dump valve 205 communicates with the outlet plugs 206 via a connecting rod 207, controlling the flow of fluid from the process tanks 201 to the drain tank 202. The drain tank 202 has an angled base, allowing it to be fully drained via an outlet port 213. A fluid/air separator tank 203 is connected to a blower exhaust pump (not shown) via the exhaust port 212. Nitrogen inlets 226 are provided to permit nitrogen gas to be introduced to the process tank 201 as described in more detail below. Also included but not shown in FIG. 5 are reservoir tanks for holding chemical cleaning solution, pumps for fluid circulation and sensors which monitor fluid levels, flow rates and temperature.

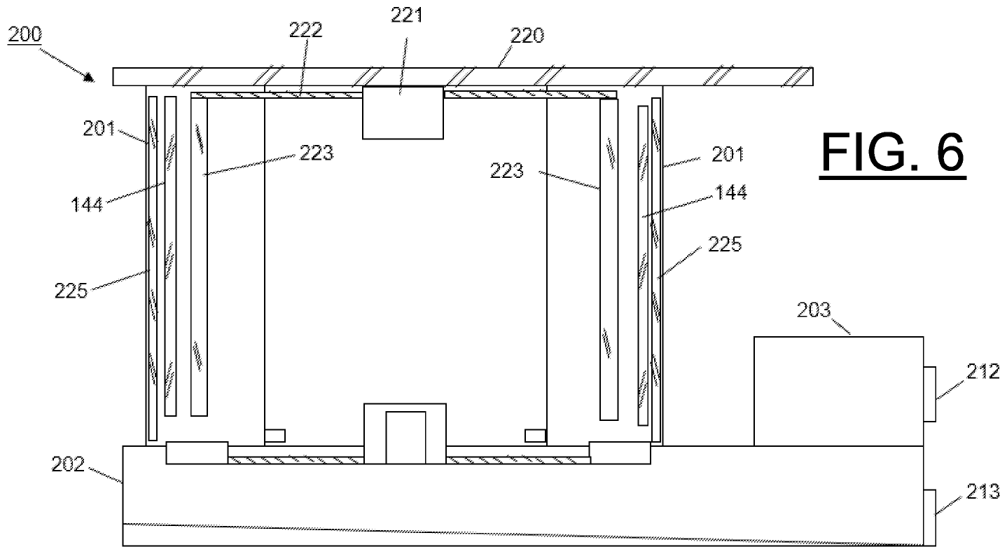

FIG. 6 shows additional components of the automated cleaning module 200, including a supporting frame 220, which supports a pneumatic actuator assembly 221 which is operative to effect motion in two axes, i.e. horizontally and vertically. The actuator assembly 221 communicates with two brush assemblies 223, each located within a respective process tank 201, via a coupling rod 222, providing horizontal extension and vertical translation to each brush assembly 223 within its respective process tank 201. The actuator assembly 221 is thereby operative to move the brush assemblies 223 horizontally into contact with the contact seal strips 121, 122, and agitate the surface of the contact seal strips 121, 122 through contacting vertical displacement relative to the contact seal strips 121, 122. Each brush assembly 223 may comprise a single brush or brush-like object which extends along the length of a respective contact seal strip 121, 122. FIG. 6 also shows a pneumatic actuator 144 similar to that shown in FIGS. 3 and 4A, 4B, and substrate holder alignment supports 225. The pneumatic actuators 144 are permanently located in the cleaning process tank, attached to the support frame 220. The alignment supports 225 may for example comprise wheels or other guides which position the contact seal strips 121 and 122 in the process tank 201. When the workpiece holder 100 is inserted into the cleaning module 200, pneumatic actuators 144 are in their un-inflated state, and there is sufficient clearance to insert the contact seal strips 122 and 121 over the pneumatic actuators 144.

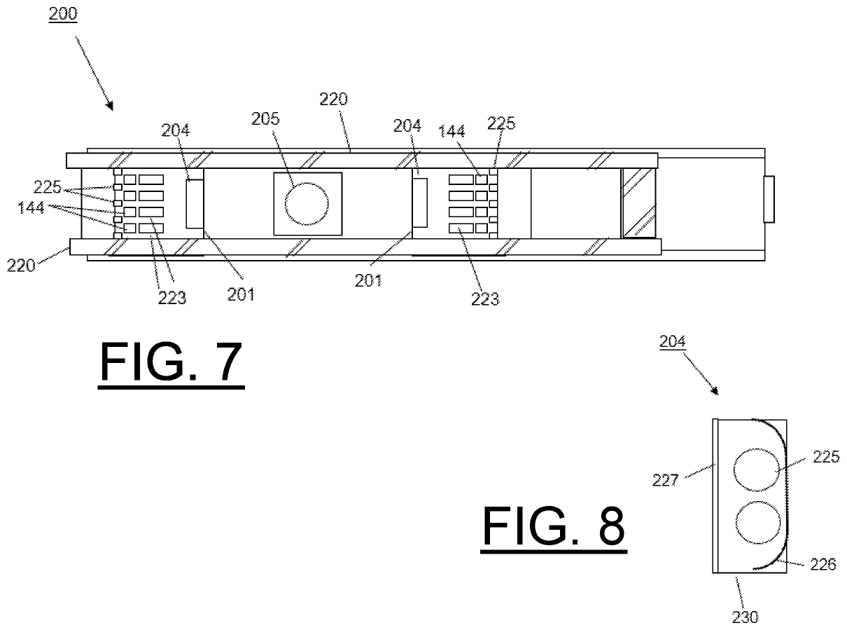

FIG. 7 is a top plan view of the automated cleaning module 200, showing that the system is capable of cleaning multiple workpiece holders in parallel. Although illustrated with four cleaning slots, the system may be configured with fewer or more cleaning slots. FIG. 7 also shows the substrate holder alignment supports 225, pneumatic actuators 144 and agitation brush assemblies 223. The alignment supports 225 provide alignment of flexure legs 111 and 112 upon insertion of a workpiece holder 100 such as that shown in FIG. 3, which thereby align contact seal strips 121 and 122 with respect to pneumatic actuator 144 and brush assembly 223. The pneumatic actuators 144 are shown in their deactivated position, in which workpieces W can be inserted into or removed from contact seal strips 121 and 122. Each process tank 201 is provided with a respective UV light source assembly 204 which is operative to illuminate the fluid and workpiece holder to be processed. In the embodiment shown, each light source assembly 204 is mounted to an internal surface of its respective process tank 201 so that it is arranged to illuminate the respective workpiece holder. Although in FIG. 7 each light source assembly 204 is shown within a respective process tank 201, in alternative embodiments each light source assembly 204 may instead be mounted outside the process tanks 201. In this case, optical windows may be provided in the walls of the respective process tanks 201 proximate the respective light source assembly 204 such that the light source assemblies 204 may illuminate the fluid and workpiece holder through their respective optical windows. The optical windows are adapted to be transparent at the illumination wavelengths.

FIG. 8 shows the light source assembly 204 in more detail. The light source assembly 204 comprises a housing 230 containing a light source 225, reflecting focusing mirrors 226, and an optical window 227. The light source 225 may for example comprise one or more vapor lamps, LEDs or other sources which provide sufficient radiant flux at the desired wavelengths. It has been found that applying light at wavelengths between 100-450 nm (i.e. ultraviolet light (UV)), optionally between 200-400 nm, optionally between 250-400 nm, provides a particularly beneficial cleaning effect. Providing UV light at more than one subrange within the 100-450 nm main range, for example providing UV light at both the UV-A and UV-C subranges, has also been found to be beneficial. The reflecting focusing mirrors 226 are designed to provide efficient utilization of the light source 225, and maintain uniform illumination in the direction of the workpiece holder. The UV irradiation may be maintained between 5 and 100 minutes, optionally between 5 and 60 minutes, optionally between 20 and 60 minutes. The illumination need not be maintained constantly, but could for example by supplied in two or more time-spaced periods.

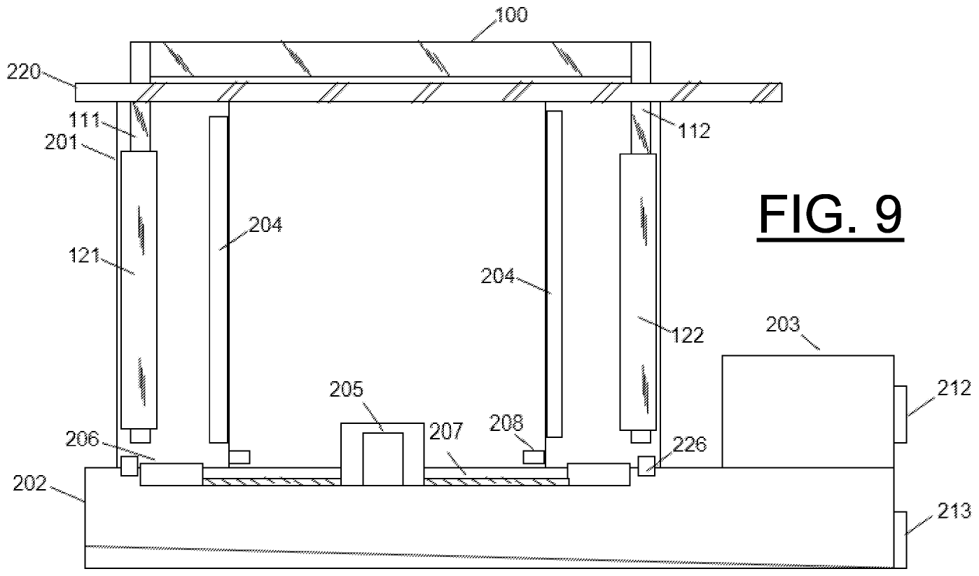

FIG. 9 shows the automated cleaning module 200 with a workpiece holder 100 inserted for cleaning. Agitation of the fluid can be accomplished by, for example, bubbling nitrogen from nitrogen inlet 226, agitation of the brush assemblies 223 or, in an alternative embodiment, by causing fluid circulation to and from an external chemistry reservoir tank (not shown). In a further embodiment, agitation of the fluid may be achieved by a combination of these processes, e.g. by using both agitation of the brush assemblies 223 and by fluid circulation to and from an external chemistry reservoir tank. In some embodiments, cleaning fluid in the cleaning module 200 may be pumped out and replaced with deionized water for rinsing, followed by drying. Alternatively, the workpiece holder 100 may be removed from the tank after chemical cleaning and moved to separate modules (not shown) for rinsing and drying operations.

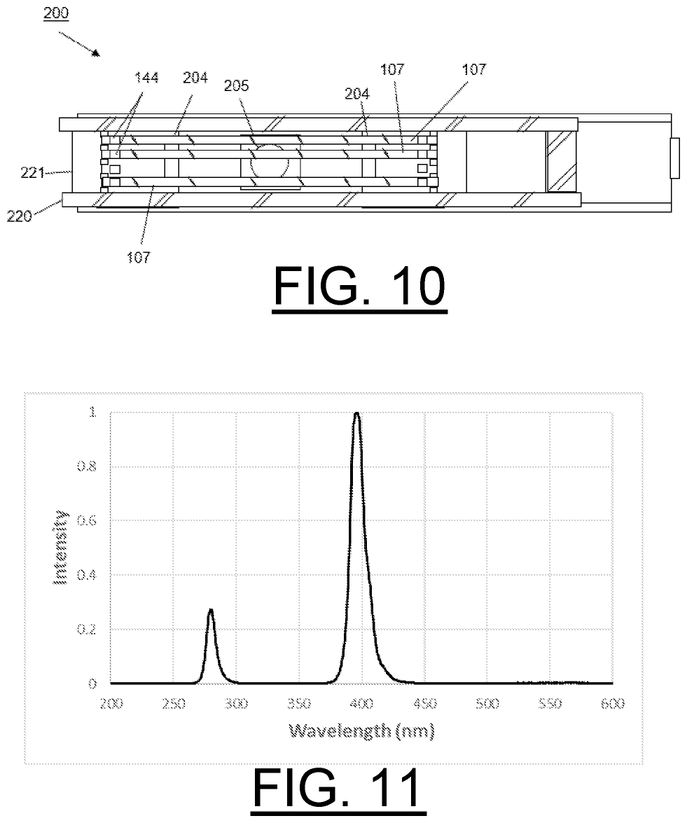

FIG. 10 schematically shows a top plan view of automated cleaning module 200 showing three workpiece holders 100 inserted for cleaning, with their respective header members 107 being visible. Pneumatic actuators 144 are shown in their activated position, in which the contact seal strips 121 and 122 are opened to allow access to chemistry, and illumination from the light source 204. The light source in FIG. 10 has direct view of the surfaces to be cleaned. The light source power and distance to the surface is chosen to provide relatively uniform illumination at an intensity of at least 50 mW/m² at the UV-C wavelength, optionally at least 100 mW/m² at the UV-C wavelength, optionally at least 150 mW/m² at the UV-C wavelength, optionally at least 200 mW/m² at the UV-C wavelength, as measured at the surface to be cleaned.

FIG. 11 graphically shows a light spectrum measured from an exemplary UV illumination source 204 which comprises an assembly of dual-frequency LEDs, with wavelengths at 400 and 280 nm. Such dual-wavelength LEDs are available as UV-C Flex strips from LED Supply of Randolph, Vt. for example.

Cleaning Chemistry

Various fluids may be suitable for introduction into the process tanks 201 for the cleaning of workpiece holders, while the workpiece holders are illuminated with UV light. These include: potassium hydroxide (KOH), sodium hydroxide (NaOH), ammonium hydroxide (NH₄OH) and other alkaline media at a concentration between 5-10% by volume, sulfuric acid (H₂SO₄) at a concentration of 0.5M-10M and a mixture of sulfuric acid at a concentration of 0.5M-10M with hydrogen peroxide (H₂O₂) at 0.1M-4M. When used at room temperature for a period of between 5-60 minutes, these fluids provide satisfactory cleaning results when combined with UV light illumination. In particular, these fluids were found to provide satisfactory cleaning when combined with UV illumination from a UV source capable of providing 594 mW/m² UV-A and 175 mW/m² UV-C at a surface 5 cm from the UV source, preventing subsequent plate-out after 50-200 substrate processing cycles.

Process

A methodology for cleaning workpiece holders in accordance with the present invention may be summarized as follows:
1. Insert at least one workpiece holder;
2. Activate pneumatic actuators 144 to open the contact seal strips 121 and 122;
3. Fill process tanks 201 with cleaning chemistry via inlets 208;
4. Turn on UV light source assembly 204;
5. Optionally—engage brush assemblies 223 using horizontal actuator assembly 221;
6. Optionally—brush inserted workpiece holder(s) using repetitive vertical motion of actuator 221;
7. Recycle the cleaning chemistry from the process tanks 201 to the drain tank 202 using valve 205;
8. Fill process tanks 201 with recycled water via inlets 208 to rinse the workpiece holders;
9. Agitate the inserted workpiece holder(s) with brush assemblies 223;
10. Drain the rinse water from the process tanks 201 using valve 205;
11. Fill process tanks 201 with clean de-ionized water via inlets 208 and rinse the inserted workpiece holder(s);
12. Drain the rinse water from the process tanks 201 using valve 205 and store the drained rinse water for reuse;
13. Deactivate pneumatic actuators 144 to close the contact seal strips 121 and 122; and
14. Remove the workpiece holder(s) from the process tanks 201.

TABLE 1 shows the results of experiments comparing various cleaning conditions:

TABLE 1
Cleaning experiments using combinations
of chemistry and light illumination.

| | Sn Detected | Plate-out | Number of plate- |
|---|---|---|---|
| Clean condition | on EDS | seen | out samples |
| KOH + UV | no | no | 12 |
| Sulfuric acid/Hydrogen | no | no | 3 |
| Peroxide Mixture + UV | | | |
| WITHOUT Clean | yes | yes | 20+ |
| KOH clean only | yes | yes | 8 |
| Sulfuric acid/Hydrogen | yes | yes | 3 |
| Peroxide Mixture only | | | |

Portions of contact seal strips 121 and 122 were cut into sample sections consisting of a central metal support region and an outer Viton coating region. To simulate a typical lifespan of use, the samples were subject to 200 cycles of immersion, with each cycle comprising immersion in tin plating bath chemistry followed by rinsing in deionized water and drying. The samples were tested for the presence of a tin oxide film on the Viton coating region using two methods. A first method used energy dispersive X-ray spectroscopy (EDS). A second method looked for the presence of metallic tin plated on the Viton after the samples were immersed into tin plating bath, with the central metal support region connected to the negative terminal of a power supply and used as a cathode. If the metallic tin spread to the Viton areas, that indicated the presence of a conducting tin oxide film. In that case, the test result in the “Plate-out seen” column of Table 1 is listed as “yes”, otherwise it is listed as “no”.

For samples listed as “WITHOUT Clean” in Table 1, these two tests were performed after the immersion cycles without any cleaning activity, and so served as an experimental baseline. The other samples were cleaned using the various conditions listed in the table above before testing for tin oxide. The results showed that using either potassium hydroxide or a mixture of sulfuric acid and hydrogen peroxide was able to reduce the number of plate-out samples compared to the baseline. However, the addition of UV light with either potassium hydroxide or with a mixture of sulfuric acid and hydrogen peroxide was even more effective than using these cleaning chemistries without the UV light, with no plate-out samples observed. This beneficial effect of UV light application in combination with cleaning chemistry is both remarkable and unexpected.

While the above-described embodiments relate specifically to the cleaning of tin oxide films from a workpiece holder, the methodology of the present invention may be extended to the cleaning of tin oxide or other conducting films from an insulating surface of any item for use in electroplating applications. For example, the surfaces of insulating tanks and reactor vessels used in tin plating, and any insulating support members may all be cleaned using the proposed methodology.

The above-described embodiments use room-temperature cleaning. However, in alternative embodiments cleaning may be performed at different temperatures to increase cleaning speed. This may be achieved by, for example, pre-heating the cleaning chemistry before transferring it to the process tanks, or alternatively providing local immersion heaters within the process tanks.

In addition, while the above embodiments propose bubbling with nitrogen gas since this is both inert and relatively available and inexpensive, other inert gases, such as argon for example, may be used to provide a similar agitation effect.

1. A method of cleaning a conducting film containing tin oxide from an insulating surface of an item for use in electroplating applications, comprising the steps of:
i) immersing the item in a cleaning fluid; and
ii) irradiating the immersed item with light of wavelength in the range 100 nm-450 nm.

2. The method of claim 1, wherein the item comprises a workpiece holder for holding a workpiece within a plating solution.

3. The method of claim 1, wherein the cleaning fluid comprises an alkaline medium.

4. The method of claim 3 wherein the cleaning fluid comprises one of the group consisting of potassium hydroxide, sodium hydroxide and ammonium hydroxide.

5. The method of claim 1, wherein the cleaning fluid comprises one of the group consisting of sulfuric acid, and a mixture of sulfuric acid and hydrogen peroxide.

6. The method of claim 1, comprising the step of agitating the cleaning fluid while the item is immersed within it.

7. The method of claim 6, wherein the step of agitating the cleaning fluid comprises at least one of bubbling or jetting the cleaning solution, causing fluid circulation within the tank, or moving a brush within the tank.

8. The method of claim 6, wherein the method includes contact brushing of the areas to be cleaned.

9. The method of claim 1, wherein step ii) comprises irradiating the immersed item with light having an intensity of at least 50 mW/m² in the UV-C band at the surface of the item to be cleaned.

10. The method of claim 1, for cleaning a workpiece holder having a contact sealing strip with workpiece gripping surfaces operative to grip a workpiece therebetween in use, comprising the step of opening the contact sealing strip of the workpiece holder to expose the workpiece gripping surfaces to the cleaning fluid.

11. A cleaning apparatus for cleaning a conducting film containing tin oxide from an insulating surface of an item for use in electroplating applications, comprising:
a tank holding cleaning fluid in use,
a support for supporting the item within the tank so that it is immersed in the cleaning fluid,
a light source configured to irradiate the item while immersed in the cleaning fluid, the light source operative to emit light in the wavelength in the range 100 nm-450 nm.

12. The cleaning apparatus of claim 11, comprising first and second tanks, each holding cleaning fluid in use, arranged such that, where the item comprises a workpiece holder, each of said first and second tanks may receive a respective depending leg of the workpiece holder.

13. The cleaning apparatus of claim 11, comprising agitation means for agitating the cleaning fluid while the item is immersed within it.

14. The cleaning apparatus of claim 13, wherein agitation means comprises a movable brush.

15. The cleaning apparatus of claim 13, wherein the agitation means comprises a source of bubbles, optionally a source of nitrogen bubbles.

16. The cleaning apparatus of claim 13, wherein the agitation means comprises means for circulating fluid within the tank.

17. The cleaning apparatus of claim 16, wherein the agitation means comprises an external tank and means for causing circulation of fluid between the tank and the external tank.

18. The cleaning apparatus of claim 11, wherein the support comprises an actuator for flexing the immersed item to expose a surface of the item to the cleaning fluid.

19. The cleaning apparatus of claim 18, wherein the item comprises a workpiece holder, and the actuator is operative to open a contact sealing strip of the workpiece holder to expose workpiece gripping surfaces to the cleaning fluid, the workpiece gripping surfaces operative to grip a workpiece therebetween in use.

20. An electroplating machine comprising the cleaning apparatus of claim 11.
